(19) United States
(12) Patent Application Publication
(10) Pub. No.: US 2010/0167534 A1
(43) Pub. Date: Jul. 1, 2010

(54) METHOD FOR FABRICATING A SEMICONDUCTOR CHIP DEVICE HAVING THROUGH-SILICON-VIA (TSV)

(76) Inventor: Ronald Takao IWATA, Hukou Shiang (TW)

Correspondence Address: Muncy, Geissler, Olds & Lowe, PLLC, 4000 Legato Road, Suite 310, FAIRFAX, VA, 22033, US

(21) Appl. No.: 12/722,251

(22) Filed: Mar. 11, 2010

Related U.S. Application Data
(62) Division of application No. 11/984,785, filed on Nov. 21, 2007.

(51) Int. Cl. H01L 21/768

(52) U.S. Cl. 438/667; 257/E21.597

(57) ABSTRACT

A semiconductor device with TSV and its fabrication method are revealed. The semiconductor device primarily comprises a chip and a flexible metal wire inside. A redistributed trace layer and a passivation layer are formed on the active surface of the chip. A through hole penetrates the chip from the active surface to the back surface, in which an insulation layer is disposed. The flexible metal wire has a first terminal and a second terminal where the first terminal is bonded to a redistributed pad of the redistributed trace layer and the second terminal passes through the through hole and protrudes from the back surface of the chip. Therefore, the flexible metal wire passing through the chip has two protruded integral terminals to achieve high stress resistance TSV with lower costs for good electrical connections of vertical stacking chips.

### CROSS REFERENCE TO RELATED APPLICATIONS

This application is a Divisional of co-pending application Ser. No. 11/984,785, filed on Nov. 27, 2007, and for which priority is claimed under 35 U.S.C. §120, the entire contents of which are hereby incorporated by reference.

### FIELD OF THE INVENTION

The present invention relates to interconnection technologies within semiconductor chips, especially to a method for fabricating semiconductor chip devices with Through-Silicon-Via (TSV).

### BACKGROUND OF THE INVENTION

Integrated circuits (IC) are fabricated on the active surface of a chip. Conventionally the electrical terminals of a chip are only formed on the active surface such as bonding pads. In order to increase package densities within the smallest footprint, a plurality of chips are vertically stacked with electrical terminals disposed not only on the active surfaces of a chip but also on the back surface to increase the electrical interconnections between chips. This is why the Through-Silicon-Via (TSV) connection is developed, TSV's electrically connect vertically stacked chips through the electrical terminals on the active surfaces as well as on the back surfaces of the chips. However, the existing TSV technologies involve many front-end semiconductor fabrication processes and materials such as a plurality of photo masks, a plurality of photolithography, sputtering, electrical plating processes and also many back-end packaging manufacture processes such as chip alignment, chip bonding, solder ball placement, etc. In order to fill conductive materials into TSV, the most common processes should include the steps as follows. TSV, which is still a blind via but not through hole (TH) in a wafer form, has to be covered with dielectrics in advance to form a dielectric via, then a conductive seed layer was disposed in the dielectric via and followed by electrical plating of conductive materials, and then finally the TSV in wafer. The wafer is lapped until TSV is exposed from the back surface of the wafer. Due to the complicated fabrication method of TSV, the processes become unstable with lower yields and higher costs. A conventional TSV technology is taught by Mashino, revealed in US patent application publication No. US 2003/0092256 A1.

As shown in FIG. 1, a conventional semiconductor device 100 primarily comprises a chip 110, a redistributed pad 120, a passivation layer 130, conductive materials 160 filled in a plurality of through holes 140 (TH) and an insulation layer 150. The chip 110 has an active surface 111 and an opposing back surface 112. Redistributed pads 120 are electrically connected to the bonding pads of the chip (not shown in figures), and the passivation layer 130 are disposed over the active surface 111 of the chip 110 except the redistributed pads 120. The through holes 140 are formed through the corresponding redistributed pads 120 and penetrate from the active surface 111 to the back surface 112, then the conductive materials 160 are filled and wafer is backside lapped. However, during TSV fabrication, the through hole 140 is not actually “penetrate” the chip 110 but is a blind via to deposit a dielectric layer 113 and a seed layer 170. The dielectric layer 113 is formed inside the through holes 140 for electrical insulation. The seed layer 170 is disposed in the through holes 140 and formed on the insulation layers 150 to electrically connect to the corresponding redistributed pads 120 for plating the conductive materials 160. In order to provide vertically electrical connections through the chip 110, the conductive materials 160 are filled into the through holes 140 which are still in the stage of blind vias. Then the back surface 112 of the chip 110 is lapped until the conductive materials 160 are exposed from the back surface 112 of the chip 110. After wafer lapping, the through holes 140 thus really become “through holes” instead of “blind vias”. Since the conductive materials 160 are either plated copper or doped polycrystalline Silicon, it is not easy to fill the through holes 140 without any voids leading to poor resistance to stresses causing reliability issues. Moreover, in order to fabricate the through holes 140 with the dielectric layer 113 and the conductive seed layer 170, and the conductive materials 160, the front-end semiconductor processes are implemented leading to higher fabrication costs.

Furthermore, the insulation layer 150 is disposed on the lapped back surface 112 of the chip 110 after wafer lapping. Then a plurality of external pads 180 are disposed at the other end of the through holes 140 on the back surface 112 of the chip 110. Another passivation layer 190 may cover the back surface 112 of the chip 110. Since the redistributed pads 120 and the external pads 180 are disposed without protruding from the active surface 111 and the bottom surface 112 of the chip 110, therefore, bumps or solder balls (not shown in the figures) are disposed as electrical connections between chip stacks or to chip carriers. Consequently, the through holes 140 and electrical insulation including the dielectric layer 113 and the insulation layer 150 are disposed in several steps and the disposition of external terminals 180 are needed, therefore, the overall fabrication method are complicated with longer lead times and higher fabrication costs.

### SUMMARY OF THE INVENTION

The main purpose of the present invention is to provide a semiconductor device with TSV (Through-Silicon-Via) and its fabrication method by using flexible metal wire in chip to pass through the through holes of the chip and to form protruded integral terminals on both ends of the through holes to provide good resistance to stresses and to provide electrical connections for vertical chip stacking and for high-density chip carriers without electrical open.

The second purpose of the present invention is to provide a semiconductor device with TSV and its fabrication method to provide good electrical connections between stacked chips or chip carriers and to simplify process flow to reduce fabrication lead times and costs.

According to the present invention, a semiconductor device with TSV primarily comprises a chip, a redistributed trace layer, a passivation layer, a through hole, an insulation layer, and a flexible metal wire. The chip has an active surface, a back surface, and a bonding pad formed on the active surface. The redistributed trace layer is disposed on the active surface and includes a redistributed pad electrically connected to the bonding pad. The passivation layer is formed over the active surface of the chip to cover the redistributed trace layer with the redistributed pad exposed. The through hole is formed through the redistributed pad and penetrates the chip from the active surface to the back surface. The insulation layer is formed inside the through hole. The flexible metal wire has a first terminal and a second terminal, wherein the first terminal is bonded to the redistributed pads and the second terminal passes through the through hole and protrudes from the back surface of the chip. The fabrication process of the semiconductor device is also revealed in the present invention.

### DESCRIPTION OF THE DRAWINGS

FIG. 1 shows a partial cross-sectional view of a conventional semiconductor device with TSV.

FIG. 2 shows a partial cross-sectional view of a semiconductor device with TSV according to the first embodiment of the present invention.

FIGS. 3A to 3L show the partial cross-sectional views of a semiconductor device with TSV during fabrication method according to the first embodiment of the present invention.

FIG. 4 shows a cross-sectional view of a metal layer formed in the through hole of another semiconductor device with TSV according to the first embodiment of the present invention.

FIG. 5 shows a cross-sectional view of a plurality of stacked semiconductor devices with TSV according to the first embodiment of the present invention.

FIG. 6 shows a partial cross-sectional view of a semiconductor device with TSV according to the second embodiment of the present invention.

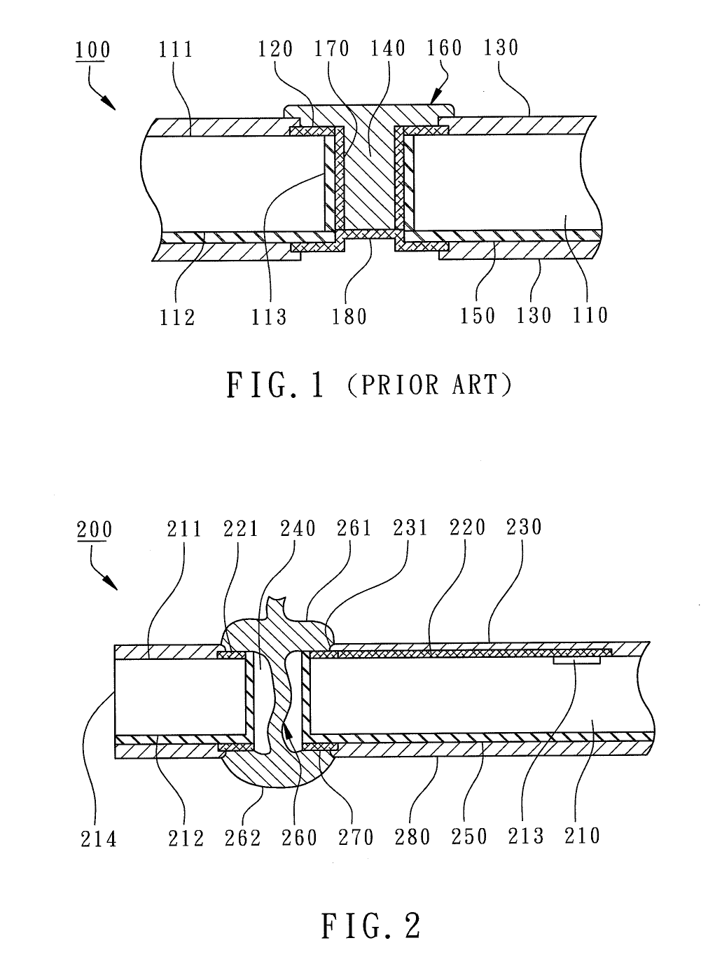

### DETAIL DESCRIPTION OF THE INVENTION

Please refer to the attached drawings, the present invention will be described by means of embodiment(s) below.

According to the first embodiment of the present invention as shown in FIG. 2, a semiconductor device 200 with TSV primarily comprises a first chip 210, a redistributed trace layer 220, a first passivation layer 230, a plurality of through holes 240, an insulation layer 250, and a plurality of flexible metal wires 260. The chip 210 has an active surface 211, a back surface 212, and a plurality of bonding pads 213 formed on the active surface 211. Therein, only one of the through holes 240, one of the metal wires 260 and one of the bonding pads 213 are shown in FIG. 2. A variety of integrated circuits (IC) are formed on the active surface 211 and are electrically connected to the bonding pads 213. The material of the chip can be Si, GaAs, or other semiconductor materials.

The redistributed trace layer 220 is electrically conductive and is disposed on the active surface 211. The redistributed trace layer 220 includes a plurality of redistributed pads 221 electrically connected to the bonding pads 213 to change the locations of the electrical terminals of the chip 210, i.e., from the locations of the bonding pads 213 to the redistributed pads 221. In the present embodiment, the redistributed pads 221 are located at the peripheries of the active surface 211 of the chip 210 without any integrated circuits under them. The first passivation layer 230 is an electrically isolating material formed over the active surface 211 of the chip 210 where the first passivation layer 230 covers the redistributed trace layers 220 with the redistributed pads 221 exposed. Preferably, the first passivation layer 230 has a plurality of openings aligned with the redistributed pads 221, which diameters are larger than the ones of the through holes 240 so that the redistributed pads 221 have exposed surfaces surrounding the through holes 240 for bonding one end 261 of the flexible metal wires 260.

The through holes 240 are formed through the corresponding redistributed pads 221 and penetrate the chip 210 from the active surface 211 to the back surface 212. The insulation layer 250 is formed inside the through holes 240. Preferably, the insulation layer 250 can further be formed over the back surface 212 of the chip 210 to prevent leakage current and electrical short.

Each flexible metal wire 260 has a first terminal 261 and a second terminal 262, as shown in FIG. 2. The first terminals 261 are bonded to the redistributed pads 221, preferably, to protrude from the active surface 211. The second terminals 262 pass through the through holes 240 and protrude from the back surface 212 of the chip 210. Therein, the first terminals 261 of the flexible metal wires 260 are the ball bonds formed by wire-bonding technology to electrically connect to the redistributed pads 221 so as to protrude from the active surface 211 of the chip 210.

The semiconductor device 200 may further comprises a plurality of external pads 270 corresponding to the through holes 240 disposed on the back surface 212 of the chip 210. A second passivation layer 280 is disposed on the back surface 212 of the chip 210 to protect and secure the external pads 270. To be more specific, the second terminals 262 of the flexible metal wire 260 can be ball bonds as well and are protrusively bonded to the external pads 270 on the back surface 212 of the chip 210. Preferably, as shown in FIG. 2 again, the chip 210 has a cut side 214 adjacent to but not exposing the through holes 240 to avoid the sections of the flexible metal wires 260 between the first terminals 261 and the second terminals 262 to expose.

Therefore, the semiconductor device 200 of the present invention implements a flexible metal wire 260 passing through the through holes 240 to form two protruded integral terminals, i.e., the first terminals 261 and the second terminals 262, to reduce the cost of fabricating the TSV, to provide good resistance to stresses and good reliability, and to provide electrical connections for vertical chip stacking and for high-density chip carriers without electrical open. Furthermore, extruded electrical terminals are formed at both ends of the TSV, therefore, the disposition of bumps or solder balls is not necessary to reduce the fabrication cost and to enhance the reliability of the semiconductor device 200.

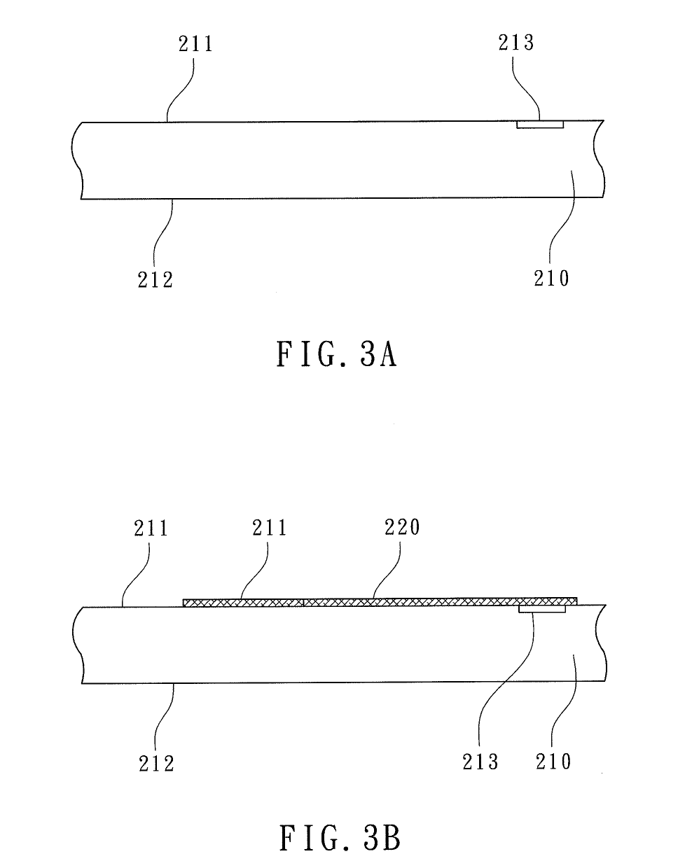

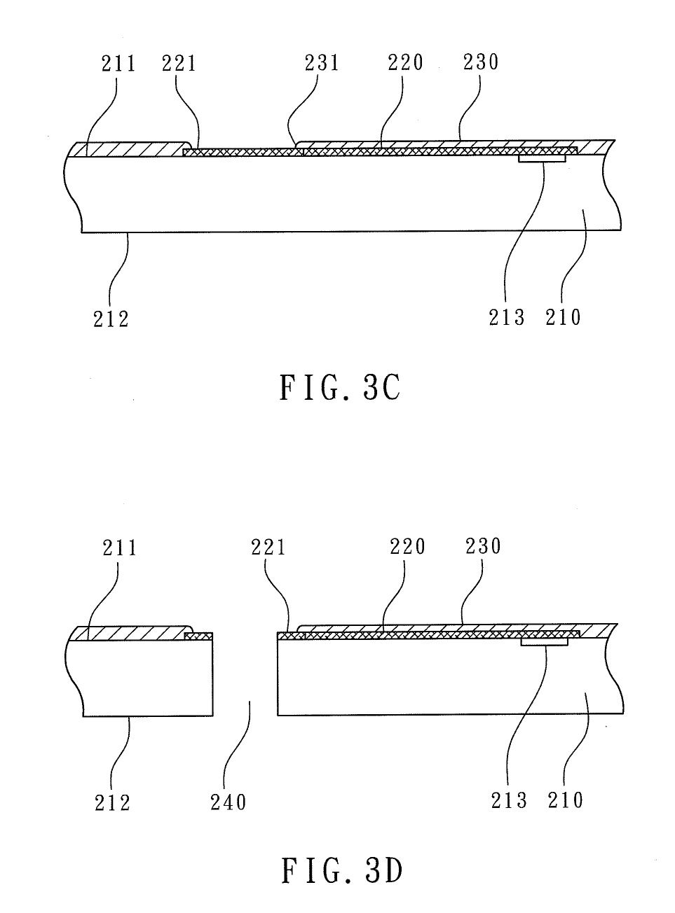

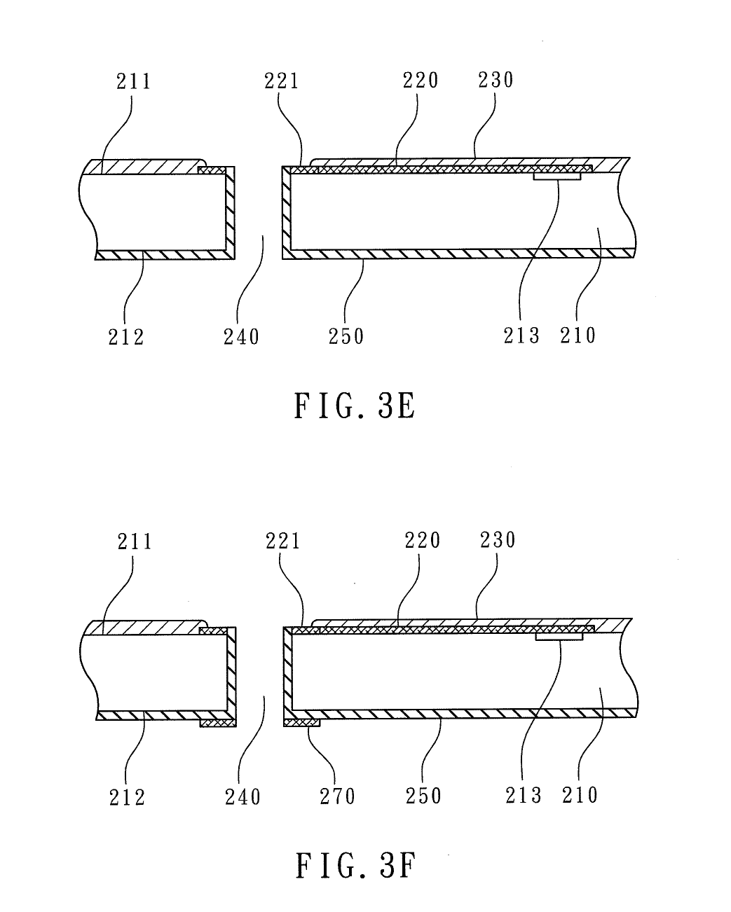

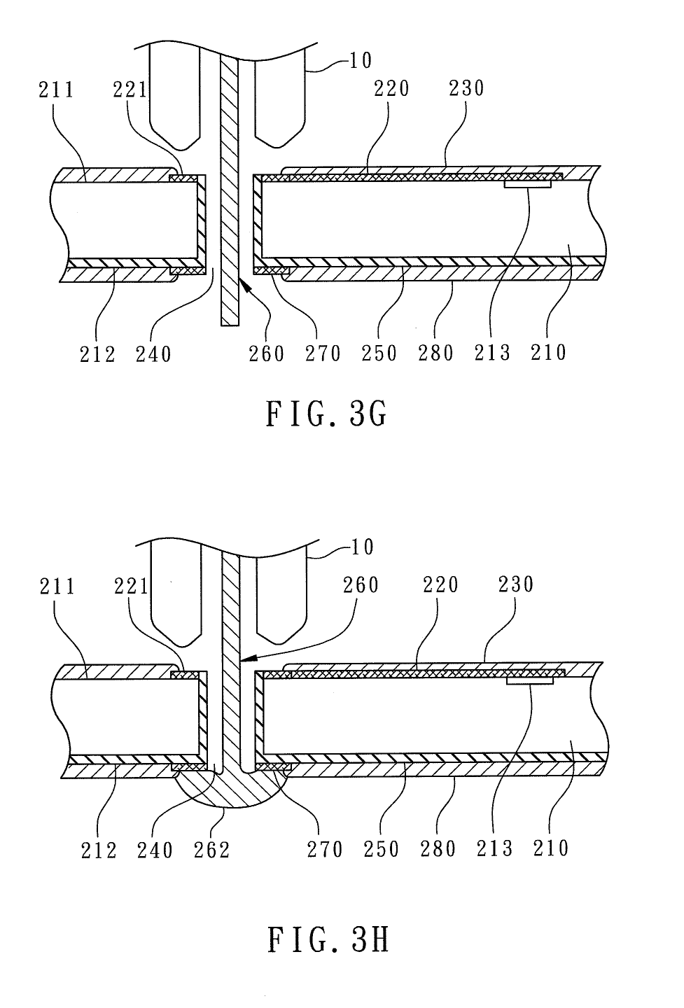

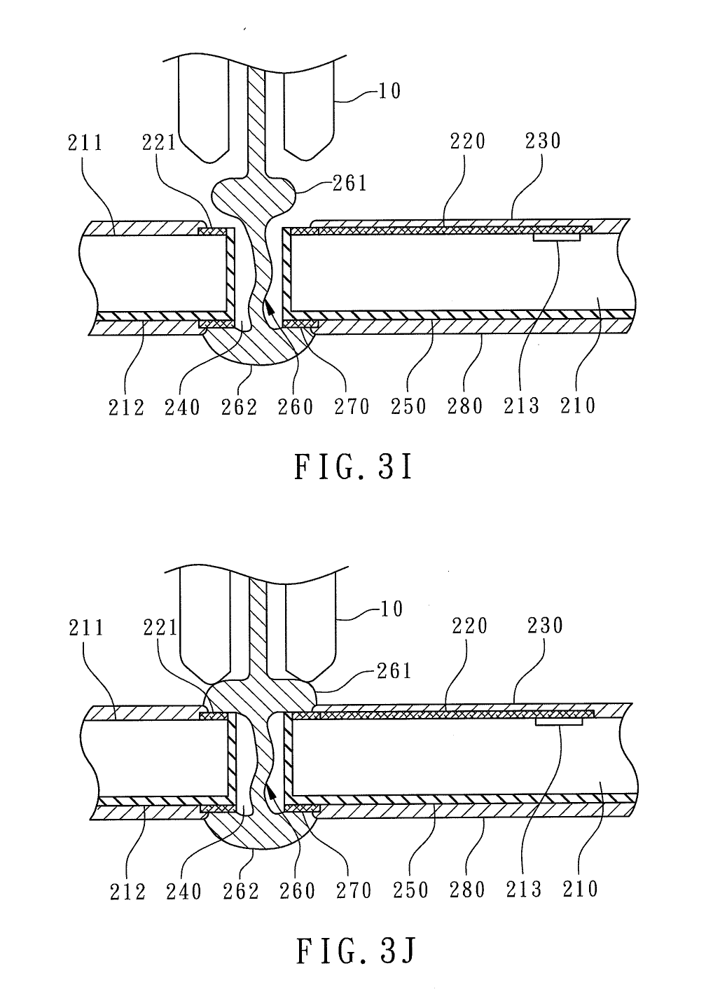

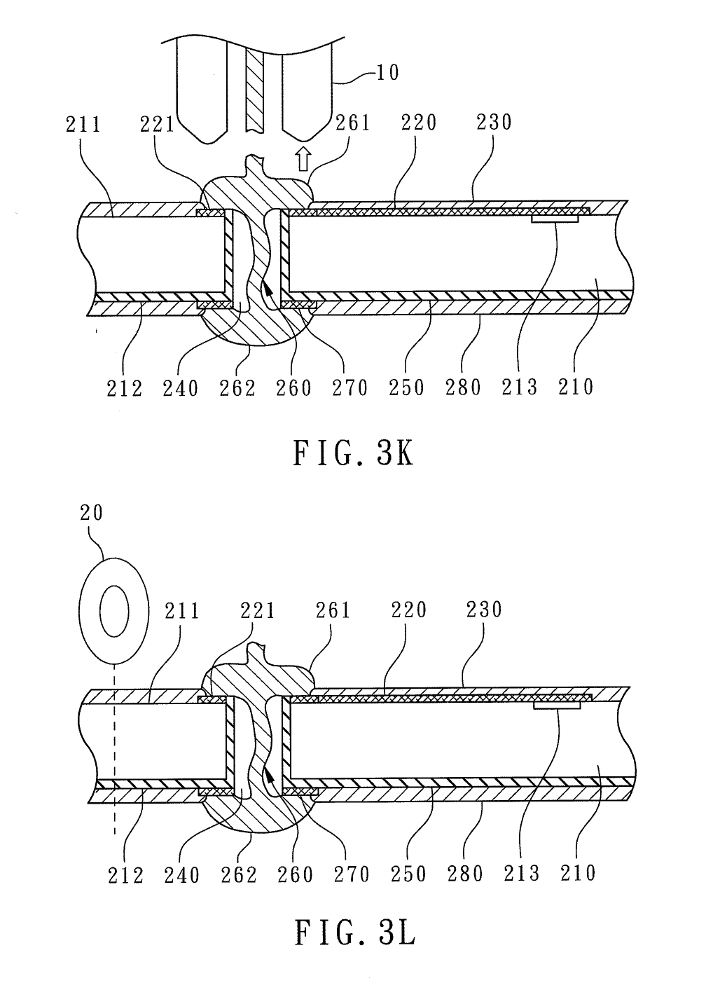

The fabrication method are described in details from FIGS. 3A to 3L to further explain the cost reduction of TSV in the present invention.

Firstly, as shown in FIG. 3A, at least a chip 210 is provided, where the chip 210 is fabricated from a wafer and having an active surface 211, a back surface 212, and a plurality of bonding pads 213 formed on the active surface 211.

Then, as shown in FIG. 3B, a redistributed trace layer 220 is disposed on the active surface 211 of the chip 210 by surface deposition and plating technologies, where the redistributed trace layer 220 includes a plurality of redistributed pads 221 connected to the bonding pads 213. Then, as shown in FIG. 3C, a first passivation layer 230 is formed over the active surface 211 of the chip 210 by chemical vapor deposition (CVD), spin coating, or printing, where the first passivation layer 230 covers the redistributed trace layer 220. The first passivation layer 230 further has a plurality of openings 231 to expose the corresponding redistributed pads 221 by photolithography or by plasma etching.

Then, as shown in FIG. 3D, a plurality of through holes 240 are formed through the redistributed pads 221 and the chip 210 by laser drilling or by reactive ion etching (RIE), where the through holes 240 further penetrate the chip 210 from the active surface 211 to the back surface 212 to form TSV in one single step. If necessary, wafer lapping can be performed during the providing process of the chip 210 or skipped. However, wafer lapping also can be performed after forming TSV.

Then, as shown in FIG. 3E, an insulation layer 250 is formed inside the through holes 240 by deposition or by thermal oxidation, where the insulation layer 250, in the present embodiment, can further be formed over the back surface 212 to protect and electrically isolate the back surface 212 of the chip 210.

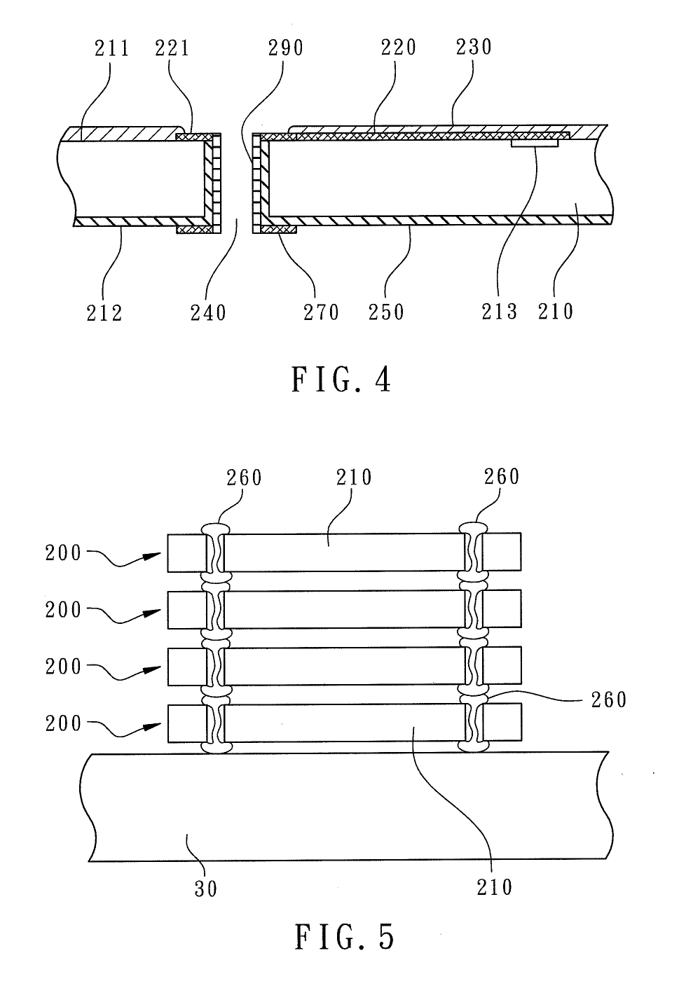

Optionally, as shown in FIG. 3F, a plurality of external pads 270 are disposed on the back surface 212 of the chip 210 corresponding to the through holes 240, which is preferable but not necessary. In another embodiment, a metal ring 290 may be formed on the insulation layer 250 inside the through holes 240 as shown in FIG. 4. The metal ring 290 is disposed inside the through holes 240 to electrically connect the corresponding redistributed pads 221 where the flexible metal wires 260 can have no mechanically bonding connection with the metal ring 290 without affecting by the stresses from the metal ring 290.

Optionally, as shown in FIG. 3G, a second passivation layer 280 is formed over the back surface 212 of the chip 210 to protect the chip 210, wherein a flexible metal wire 260 is provided by a wire capillary 10 for disposing inside the corresponding through holes 240 of the chip 210. A pre-designed length of the wire 260 is pulled first so that the end of the flexible metal wire 260 can pass through the chip 260 from the active surface 211 to the back surface 212 and extruded from the back surface 212. Then, as shown in FIG. 3H, a ball bond is formed at the extended end of the flexible metal wire 260 by ball bonding technology, where the diameter of the ball bond is larger than the one of the through hole 240. Under suitable bonding strengths and bonding temperatures, the extended end of the flexible metal wire 260 will be extruded and bonded on the external pads 270 to form the second terminal 262 of the flexible metal wire 260.

Then, as shown in FIG. 3I, another ball bond is formed by ball bonding technology from pre-designed section of the flexible metal wire 260 close to the redistributed pads 221 on the active surface 211. Then, as shown in FIG. 3J, the ball bond is bonded to the redistributed pads 221 by pressing the wire capillary 10 against the redistributed pads 221 to form the first terminal 261 of the flexible metal wire 260.

Then, as shown in FIG. 3K, the flexible metal wire 260 is cut from the top of the ball bond, i.e., the first terminal 261, to complete a flexible metal wire 260 in TSV. Repeat the processing steps from FIG. 3G to FIG. 3K, to individually form a flexible metal wire 260 in every TSV.

Finally, as shown in FIG. 3L, the step of wafer dicing is performed after disposing the flexible metal wires 260. By means of a sawing tool 20, a plurality of chip 210 are separated from a wafer to form individual semiconductor devices 200 as shown in FIG. 2. The cut side 214 mentioned above is formed during the wafer-dicing step.

As shown in FIG. 5, a plurality of semiconductor devices 200 can be stacked to form a 3D packages by aligning, bonding, and stacking the flexible metal wires 260 on the semiconductor devices 200 to form electrical connections between the stacked semiconductor devices 200 to easily manufacture high-density multi-chip stacking 3D packages. During multi-chip stacking processes, there is no further electrical interconnection inside a chip needed. Moreover, the stacking of chips becomes easier.

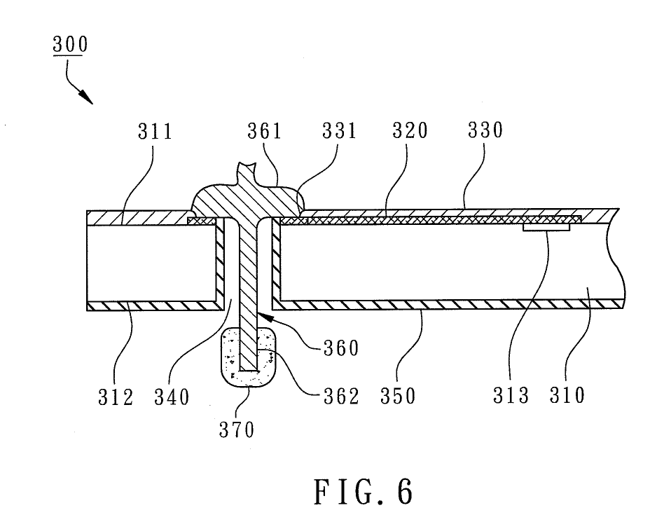

In the second embodiment of the present invention, as shown in FIG. 6, another semiconductor device with TSV is revealed. The semiconductor device 300 primarily comprises a chip 310, a redistributed trace layer 320, a passivation layer 330, a plurality of through holes 340, an insulation layer 350, and a plurality of flexible metal wires 360. The chip 310 has an active surface 311, a back surface 312, and a plurality of bonding pads 313 formed on the active surface 311. The redistributed trace layer 320 is formed on the active surface 311 and includes a plurality of redistributed pads 321 electrically connected to the bonding pads 313. The passivation layer 330 is formed over the active surface 311 of the chip 310 to cover the redistributed trace layer 320. The passivation layer 330 further has a plurality of openings 331 to expose the corresponding redistributed pads 321 for bonding the flexible metal wires 360.

The though holes 340 are formed through the corresponding redistributed pads 321 and penetrate the chip 310 from the active surface 311 to the back surface 312. The insulation layer 350 is formed inside the through holes 340. Preferably, the insulation layer 350 is further formed over the back surface 312 of the chip 310 to protect the chip 310. Each flexible metal wire 360 has a first terminal 361 and a second terminal 362 where the first terminal 361 is bonded to the redistributed pad 321 and the second terminal 362 passes through the through hole 340 and protrudes from the back surface 312 of the chip 310. In the present embodiment, the first terminals 361 are ball bonds and the second terminals 362 are suspended to be movable with respect to the redistributed pad 321 so that the passivation layer on the back surface 312 of the chip 310 can be eliminated to simplify fabrication method and to save fabrication costs. Preferably, solder paste 370 is disposed on the second terminals 362 of the flexible metal wire 360 for external soldering.

In conclusions, the flexible metal wires 360 in the present invention pass through the through holes 340 of the chip 310 to form the first extruded terminals 361 on the active surface 311 and the second extruded terminals 362 on the back surface 312 as external electrical terminals which are integral and stress-resistant. When stacking a plurality of semiconductor devices 300, high-density connections can be achieved between the stacked semiconductor devices 300 with good electrical connections between the chips 310 or between the chip 310 and the chip carrier. Moreover, the fabrication process flow is simplified to reduce the lead times and the cost.

The above description of embodiments of this invention is intended to be illustrative and not limiting. Other embodiments of this invention will be obvious to those skilled in the art in view of the above disclosure.

What is claimed is:

1. A method for fabricating a semiconductor device with TSV (Through Silicon Via), comprising the steps of:
providing a chip having an active surface, a back surface, and a bonding pad on the active surface;
disposing a redistributed trace layer on the active surface of the chip, the redistributed trace layer including a redistributed pad electrically connected to the bonding pad;
forming a passivation layer over the active surface to cover the redistributed trace layer with the redistributed pad exposed;
forming a through hole through the redistributed pad and penetrating the chip from the active surface to the back surface;
forming an insulation layer in the through hole; and
disposing a flexible metal wire in the chip, wherein the flexible metal wire has a first terminal and a second terminal, wherein the first terminal is bonded to the redistributed pad and the second terminal passes through the through hole and protruding from the back surface of the chip.

2. The method as claimed in claim 1, wherein the passivation layer is further formed on the back surface of the chip.

3. The method as claimed in claim 1, wherein the first terminal is a ball bond which diameter is larger than the one of the through hole in a manner that the first terminal protrudes from the active surface.

4. The method as claimed in claim 3, wherein the second terminal is also a ball bond.

5. The method as claimed in claim 4, further comprising the step of disposing an external pad corresponding to the through hole on the back surface of the chip, wherein the second terminal is protrusively bonded to the external pad.

6. The method as claimed in claim 1, wherein the passivation layer has an opening aligned with the redistributed pad, which diameter is larger than the one of the through hole for bonding the first terminal of the flexible metal wire.

7. The method as claimed in claim 1, further comprising the step of disposing a metal ring on the insulation layer inside the through hole to electrically connect to the corresponding redistributed pad.

8. The method as claimed in claim 7, wherein the flexible metal wire has no mechanically bonding connection with the metal ring.

9. The method as claimed in claim 1, further comprising the step of disposing solder paste on the second terminal of the flexible metal wire.

10. The method as claimed in claim 1, wherein the second terminal of the flexible metal wire is suspended and is movable with respect to the redistributed pad.

11. The method as claimed in claim 1, wherein the chip is fabricated from a wafer, and further comprising the step of wafer dicing to singulate the chip after disposing the flexible metal wire.
